(19) United States
(12) Patent Application Publication
(10) Pub. No.: US 2010/0123612 A1
(43) Pub. Date: May 20, 2010

(54) ANALOG-TO-DIGITAL CONVERSION CIRCUIT AND DEVICE

(75) Inventors: Marco Zamprogno, Milano (IT); Federico Guanziroli, Milano (IT); Germano Nicollini, Piacenza (IT); Pierangelo Confalonieri, Milano (IT)

Correspondence Address: SEED INTELLECTUAL PROPERTY LAW GROUP PLLC, 701 FIFTH AVENUE, SUITE 5400, SEATTLE, WA, 98104-7092, US

(73) Assignee: ST-ERICSSON SA, Geneva (CH)

(21) Appl. No.: 12/622,166

(22) Filed: Nov. 19, 2009

(30) Foreign Application Priority Data
Nov. 20, 2008 (IT) MI2008A002067

(51) Int. Cl. H03M 1/34

(52) U.S. Cl. 341/158

(57) ABSTRACT

An analog-to-digital conversion circuit and device having an input stage arranged to receive an input signal and to provide an output analog signal as a function of the input signal; an analog-to-digital conversion block arranged to receive the output analog signal and to provide a respective output digital signal. The input stage includes a first voltage buffer arranged to provide the output analog signal to the conversion block as the translation of the input signal of an amount equal to a translation voltage; a second voltage buffer arranged to provide a first reference signal to the conversion block that is representative of the translation of a first reference voltage of an amount equal to the translation voltage, so that the conversion block stores the input signal as the difference of the input signal and the first reference voltage regardless of the translation voltage.

### BACKGROUND

1. Technical Field

The present disclosure relates to an analog-to-digital conversion circuit and device (ADC), preferably for mobile telephony.

2. Description of the Related Art

In mobile telephony, in some cases, an analog-to-digital conversion of single-ended type electric signals is required, i.e., of electric signals having a single voltage reference, preferably to the ground.

Generally, an analog-to-digital conversion device is arranged to receive in input a single-ended type electric signal coming from a relative external source having a distinctive output impedance which is not usually known or, if it is known, of a high value.

In these operative conditions, the need is felt to have the use of an analog-to-digital conversion device arranged for the reading of the high impedance input electric signal without incurring the typical errors associated with the division between source impedance and input impedance.

In order to meet this need, the analog-to-digital conversion device should be arranged to have also a very high input impedance, ideally an infinite one; therefore, a corresponding very low switched input or sampling capacitance (typically on the order of some fractions of pF, for example, at most of 0.3 pF), and a very high input resistance (typically of the order of some MOhms) is used.

Currently, the above requirement relative to the switched input capacitance is not found in known analog-to-digital conversion devices.

In fact, an analog-to-digital conversion device of a known design, directly arranged for the 10-bit sampling of an input electric signal, has an input capacitance of some pFs (for example, 5-6 pFs) to obviate further drawbacks related to usual problems such as, for example, the linearity or the noise. The operative choice of an input or sampling capacitance of some pFs contrasts with the choice of having a very low input or sampling capacitance value (at most equal to 0.3 pF).

In an alternative solution to the described one, the use is suggested of a unitary voltage buffer (for example, implemented with operational amplifiers) of the input electric signal arranged upstream of the analog-to-digital conversion device. Such a solution does not give an input or sampling capacitance that is as low as that required, and it also results in unreliability in terms of accuracy for conversion of single-ended type signals. This is due to the fact that, while the single-ended type analog-to-digital conversion device are arranged to convert the input signal from a ground voltage level (0V) to a predetermined reference level, which can even be very high, in any case the analog voltage buffer does not result in the ability to achieve the ground voltage level because it has active structures that begin to switch off when the voltage level is near to 0.

In other words, the single-ended type analog-to-digital conversion device with an input signal unitary voltage buffer arranged upstream has a criticality in reaching the ground voltage level.

Again, as an alternative, typically resistive structures could be employed, but this again has performance results that are unable to meet the requirement of a high input impedance.

### BRIEF SUMMARY

The present disclosure provides an analog-to-digital conversion device having an alternative and improved design and function compared to the analog-to-digital conversion devices of the above-mentioned known art, and particularly which ensures reduced conversion criticalities of a ground voltage level or another reference voltage level.

In accordance with the present disclosure, an analog-to-digital conversion device is provided that includes an input stage arranged to receive an input signal and to provide an output analog signal as a function of the input signal; and an analog-to-digital conversion block arranged to receive the analog output signal and to provide a respective output digital signal, wherein the input stage includes a first voltage buffer arranged to provide the analog output signal to the conversion block as a translation of the input signal of an amount equivalent to a translation voltage; and a second voltage buffer arranged to provide a first reference signal to the conversion block that is representative of a translation of a first reference voltage of an amount equivalent to the translation voltage, so that the conversion block stores the input signal as a difference between the input signal and the first reference voltage, regardless of the translation voltage.

In accordance with the present disclosure, a circuit is provided that includes an input stage having an input and an output, the input stage including a first transistor having a drain and a source adapted to receive first and second voltage references, respectively, and a gate adapted to receive input signals; a second transistor having a drain and a source adapted to receive the first and second voltage references, and a gate adapted to receive the first voltage reference; and a third transistor having a drain and a source adapted to receive the first and second voltage references, respectively, and a gate adapted to receive a third reference voltage, the first transistor adapted to output on its source a translated voltage input signal, the second transistor adapted to output on its source a first reference signal, and the third transistor adapted to output on its source a second reference signal.

In accordance with the present disclosure, a mobile device is provided that includes a circuit that includes an input stage having an input and an output, the input stage including a first transistor having a drain and a source adapted to receive first and second voltage references, respectively, and a gate adapted to receive input signals; a second transistor having a drain and a source adapted to receive the first and second voltage references, and a gate adapted to receive the first voltage reference; and a third transistor having a drain and a source adapted to receive the first and second voltage references, respectively, and a gate adapted to receive a third reference voltage, the first transistor adapted to output on its source a translated voltage input signal, the second transistor adapted to output on its source a first reference signal, and the third transistor adapted to output on its source a second reference signal.

### BRIEF DESCRIPTION OF THE SEVERAL VIEWS OF THE DRAWINGS

Further characteristics and advantages of the device according to the disclosure will be more readily appreciated from the description reported below of preferred exemplary embodiments, given by way of non-limiting, indicative example, when taken in conjunction with the annexed Figures, in which:

FIGS. 1 and 2 illustrate, from a circuital point of view, an analog-to-digital conversion device according to an example of the disclosure; and

FIG. 3 illustrates, from a circuital point of view, an analog-to-digital conversion device according to a further example of the disclosure.

### DETAILED DESCRIPTION

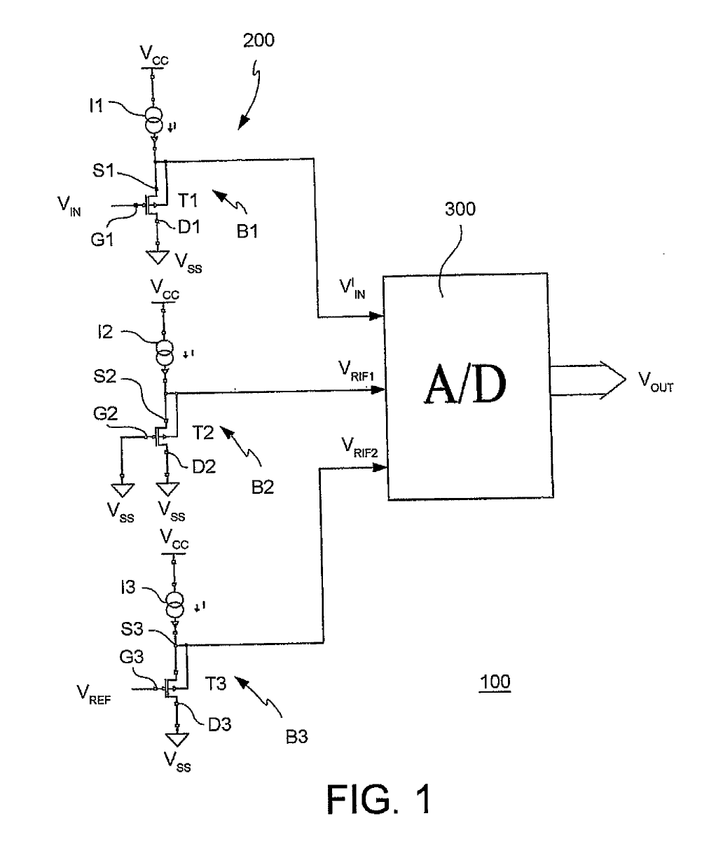

With reference to FIG. 1, an analog-to-digital conversion device 100 is now described, hereinafter also simply “conversion device,” according to an example of the disclosure.

The conversion device 100, which can be also referred to with the acronym ADC (Analogical to Digital Converter), finds application preferably in the mobile telephony technology in which single-ended type signals are employed.

The conversion device 100 includes an input stage 200 so arranged as to receive an analog-type input signal vᵢₙ coming from a conventional signal source (not shown in the Figures) and to provide an analogical output signal v_{in′} which is a function of the input signal vᵢₙ.

The conversion device 100 further includes an analog-to-digital conversion block 300, hereinafter also simply conversion block, per se known and operatively cascade-connected to the input stage 200 to receive in input the output analog signal v_{in′}, and to provide in output a respective digital signal Vₒᵤₜ.

An example of a conversion block 300 is described in U.S. Pat. No. 6,897,801 owned by the Applicant.

The input stage 200 includes a first voltage buffer B1, preferably a first source follower device.

The first source follower device B1 includes a first P-channel MOS-type transistor T1 having a predetermined channel width/length equal to W1/L1.

The first transistor T1 has the gate terminal G1 arranged to receive the input signal vᵢₙ.

The drain terminal D1 of the first transistor T1 is operatively coupled to a first reference voltage Vₛₛ, the ground potential (0V) in the example.

The source terminal S1 of the first transistor T1 is operatively coupled to a second reference voltage V_{cc}, for example, the supply voltage, through a first direct current generator I1. A typical supply voltage value for these applications is, for example, 2.5 V. The body of the first transistor T1 is electrically connected to the respective source terminal S1. The source terminal S1 of the first transistor D1 is operatively coupled to the analog-to-digital conversion block 300 in order to provide it with the input stage 200 output analog signal v_{in′}.

The first source follower device B1 is structured or arranged so that the output analog signal v_{in′} is a translation of the input signal vᵢₙ by an amount equal to a translation voltage Vₛₕ:

vᵢₙ=v_{in′}+Vₛₕ

in which Vₛₕ=Vₜₕ (threshold voltage of the first transistor T1)+Vₒᵥ (overdrive voltage of the first transistor T1).

It shall be noticed that the overdrive voltage Vₒᵥ of the first transistor T1 is the voltage that is required to allow the first transistor T1 to transfer the current I imposed by the first current generator I1.

It shall be noticed, anyhow, that the overdrive voltage Vₒᵥ of the first transistor T1 is independent from the input signal vᵢₙ, except for negligible effects for accuracy conversions of the order, for example, of 10 bit.

The input stage 200 further includes a second voltage buffer B2, preferably a second source follower device.

The second source follower device B2 includes a second P-channel MOS-type transistor T2 that is similar to the first transistor T1, i.e., having a channel width/length ratio equal to W1/L1.

The second transistor T2 has the respective gate terminal G2 operatively connected to the first reference voltage Vₛₛ. The drain terminal D2 of the second transistor T2 is also electronically coupled to the first reference voltage Vₛₛ. The source terminal S2 of the second transistor T2 is operatively coupled to the second reference voltage V_{cc}, for example, the input voltage, through a second direct current generator 12 is similar to the first current generator I1. The body of the second transistor T2 is electronically connected to the respective source terminal s2.

The source terminal S2 of the second transistor T2 is, in turn, operatively connected to the analog-to-digital conversion block 300 to provide it with a first reference signal V_{rif1}.

The second source follower device B2 is structured or arranged so that the first reference signal V_{rif1} is representative of the translation of the first reference voltage Vₛₛ by an amount equal to the translation voltage Vₛₕ:

V_{rif1}=Vss+Vₛₕ

It shall be noticed that the translation voltage Vₛₕ of the second source follower device B2 is substantially the same as the first source follower device B1 since, as already stated above, the second transistor T2 is substantially identical to the first transistor T1.

It is pointed out that a difference between the translation voltages, which is determined by statistic mismatches of the transistors and the currents results to be, in any case, sizeable at will during the device manufacturing step, therefore it is considerable as well as negligible.

The input stage 200 further includes a third voltage buffer B3, preferably a third source follower device.

The third source follower device B3 includes a third P-channel MOS-type transistor T3 completely similar to the first T1 and the second T2 transistors already described above, i.e., having a channel width/length ratio equal to W1/L1.

The third transistor T3 has the respective gate terminal G3 operatively connected to a third reference voltage V_{ref}, preferably a fraction of the second reference voltage V_{cc}. In the case where the first reference voltage V_{cc} (supply voltage) is equal to 2.5 V, the third reference voltage V_{ref} results to be equal, for example, to 1.25 V.

The source terminal S3 of the third transistor T3 is operatively coupled to the second reference voltage V_{cc}, through a third direct current generator 13, which is substantially similar to the first I1 and the second I2 current generators described above. The body of the third transistor T3 is electrically connected to the respective source terminal S3.

The source terminal S3 of the third transistor T3 is, in turn, operatively connected to the analog-to-digital conversion block 300, in order to provide it with a second reference signal V_{rif2}.

The third source follower device B3 is arranged so that the second reference signal V_{rif2} is representative of the translation of the second reference voltage V_{ref} by an amount equal to the translation voltage Vₛₕ:

V_{rif2}=V_{ref}+Vₛₕ

It shall be noticed that the translation voltage Vₛₕ of the third source follower device B3 is substantially the same as the first B1 and the second B2 source follower devices since, as already stated above, the third transistor T3 is substantially identical to the first T1 and the second T2 transistors.

Referring to the conversion block 300 of the example described, it is structured or arranged to receive in input the output analog signal v_{in′} the first reference signal V_{rif1}, and the second reference signal V_{rif2} coming from the input stage 200, respectively.

As known, the conversion block 300, in order to generate the output digital signal Vₒᵤₜ, carries out a first storing operation of the input signal vᵢₙ relative to the first reference voltage Vₛₛ (being a single-ended type conversion block), and a second comparison operation of the input signal vᵢₙ that is stored with the third reference voltage V_{ref} in order to achieve the analog-to-digital conversion of the same input signal vᵢₙ (by implementing, for example, a successive-approximation algorithm, per se known).

Referring to the first storing operation, the conversion block 300 performs, during the first storing operation, the difference between the output analog signal v_{in′} and the first reference signal V_{rif1}, as indicated herein below:

v_{in′}−v_{rif1}=vᵢₙ+vₛₕ−(Vₛₛ+Vₛₕ)

whereby, cancelling out the terms relative to the translation voltage Vₛₕ, it is obtained that:

v_{in′}−v_{rif1}=vᵢₙ−Vₛₛ

As it shall be noticed, advantageously, the stored input signal vᵢₙ is, in effect, compared to the first reference voltage Vₛₛ (in the example, the ground voltage).

Furthermore, it shall be noticed that the compensation of the translation voltage Vₛₕ allows the conversion block to recover the input signal vᵢₙ as the difference of the input signal vᵢₙ and the first reference voltage Vₛₛ independently from the translation voltage Vₛₕ.

This results to be rather advantageous, since the translation voltage Vₛₕ, being a function of the threshold voltage Vₜₕ and the overdrive voltage Vₒᵥ of the transistor T1, is process- and temperature-dependant and, for example, it would not allow the proper identification of the level 0 of the input signal Vᵢₙ by the conversion block 300.

This is due to the use of the first B1 and second B2 voltage buffers that allow having, in input at the conversion block 300, the input signal Vᵢₙ and the first reference voltage translated by the same translation voltage Vₛₕ.

As regards the second comparison operation between the stored input signal vᵢₙ and the third reference voltage V_{ref}, it is pointed out that the conversion block 300 establishes, according to a successive-approximation algorithm (per se known), whether the input signal is higher or lower compared to a comparison level that is equal to V_{ref}/2, and then compared to a comparison level that is equal to V_{ref}/4 or 3/4V_{ref}, and so on.

From an operative point of view, the conversion block 300 is structured or arranged as to contextually obtain the third reference voltage V_{ref} as a difference between the second reference signal V_{rif2} and the first reference signal V_{rif1}, as indicated herein below:

V_{rif2}−V_{rif1}=V_{ref}+Vₛₕ−(Vₛₛ+Vₛₕ)

whereby, by cancelling out the terms relative to the translation voltage Vₛₕ, it is obtained that:

V_{rif2}−V_{rif1}=V_{ref}−Vₛₛ

As it shall be noticed, the third reference voltage V_{ref} that is employed in the second comparison operation with the stored input signal vᵢₙ is obtained as the difference between the third reference voltage V_{ref} and the first reference voltage Vₛₛ (ground voltage).

Furthermore, it shall be noticed that the compensation of the translation voltage Vₛₕ allows the conversion block 300 to retrieve the third reference voltage V_{ref} as the difference of the third reference voltage V_{ref} and the first reference voltage Vₛₛ, independently from the translation voltage Vₛₕ.

This results to be rather advantageous, since the translation voltage Vₛₕ, being a function of the threshold voltage Vₜₕ and the overdrive voltage Vₒᵥ of the transistor T1, is process- and temperature-dependant, and it would not allow, for example, the proper identification of the exact level of the third reference voltage V_{ref}, thus involving the missampling of the input signal vᵢₙ by the conversion block 300.

This is due to the use of the second B2 and the third B3 voltage buffers, which allows having, in input at the conversion block 300, the input signal Vᵢₙ and the first reference voltage translated by the same translation voltage Vₛₕ.

In this manner, the conversion block 300 is such as to provide in output the digital signal Vₒᵤₜ by comparing the actual input signal Vᵢₙ to the actual third reference voltage V_{ref}.

It shall be noticed that according to the example of the disclosure described, the conversion block 300 is arranged to perform the first recovery operation of the input signal Vᵢₙ and the second recovery operation of the reference voltage V_{ref} by employing the same fixed reference, i.e., the first reference voltage Vₛₛ, that is the ground voltage (0V).

It shall be noticed that the conversion block 300 described can be referred to as being of the pseudo-differential type. Alternatively, the analog-to-digital conversion device 100 may include a differential-type conversion block.

As stated above, the analog-to-digital conversion device 100 of the described example advantageously allows comparing the input signal Vᵢₙ and the third reference voltage V_{ref} by compensating the presence of the translation voltage, and avoiding that the action of process and/or temperature variations that could condition or alter the accuracy of the reference signals and voltages that are employed by the conversion block 300 to generate the digital signal Vₒᵤₜ.

Referring back to the input stage 200, it is pointed out that the use of a first voltage buffer, particularly a first source follower device, allows having the required requirements met by an analog-to-digital conversion device that is dedicated, in particular, to single-ended type signals. Such requirements, which are typical for a source follower device, are: high input impedance (ideally, infinite), low input capacitance (below 0.3 pF), transfer linearity, and high band (typically of the order of Mhzs) necessary for the transfer from input to output of the analog signal also in the presence of a considerable capacitive charge, as the analog-to-digital conversion block 300 can be.

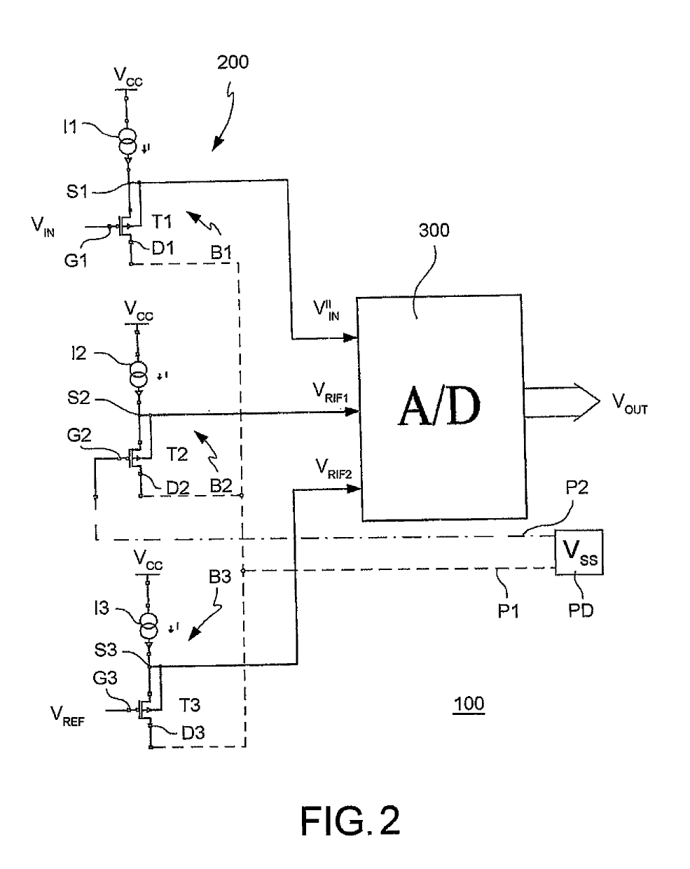

Referring now to FIG. 2, it is pointed out that, from the point of view of the circuit layout shown in FIG. 1, the drain terminals of the transistors T1, T2, and T3 are operatively connected to a common pad PD corresponding to the first reference voltage Vₛₛ through a same first electrical connection path P1, since such drain terminals are not responsible, at first approximation, for the voltage produced in output by the same transistors. This is due to the fact that, in any case, the P-channel MOS-transistors work in a saturation zone, and under these conditions the voltage at each source terminal is substantially insensitive to small voltage variations at the respective drain terminal. Therefore, the drain terminals can be connected to the common pad PD without paying any particular attention to the first path P1, being able to afford reduced voltage drops without compromising the quality of the analog-to-digital conversion device.

Instead, as regards the electric connection to the first reference voltage Vₛₛ of the gate terminal G2, it is pointed out that an optional variation of the first reference voltage Vss would involve an equal variation of the first reference signal V_{rif1}. Therefore, to obviate this drawback, the gate terminal G2 of the second transistor T2 is electrically connected to the common pad PD through a dedicated second electrical connection path P2. It shall be noticed that, since the gate G2 does not absorb current anyhow, the second path P2 can be manufactured with a relatively high resistance (even of hundreds of Ohm), without varying the first reference voltage Vss value, and with a reduced use of the area or reduced area usage.

Therefore, the particular layout shown in FIG. 2, with the first P1 and the second P2 paths mutually distinct advantageously allows manufacturing the analog-to-digital conversion device 100 with an optimal accuracy and reduced area occupancy.

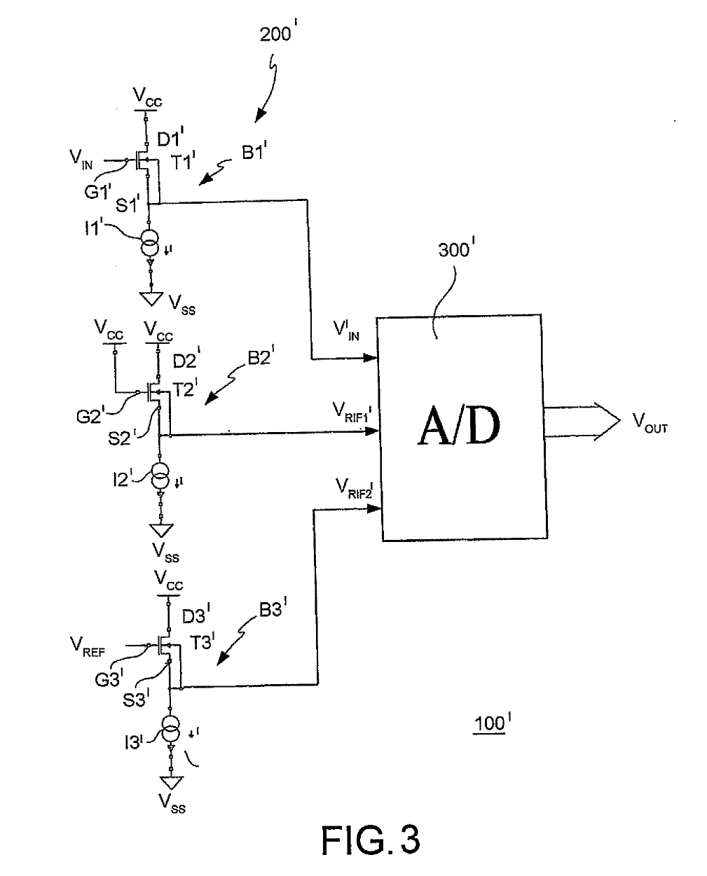

Referring to FIG. 3, an analog-to-digital conversion device 100′ according to a further embodiment is described.

The analog-to-digital conversion device 100′ is structured or arranged for the conversion of single-ended type signals relating to a first reference voltage, for example, the supply voltage.

It shall be noticed that, compared to the example of FIGS. 1 and 2, in the example of FIG. 3 the first reference voltage will be indicated with V_{cc} (supply voltage), while a second reference voltage will be indicated with Vₛₛ (ground voltage).

The analog-to-digital conversion device 100′ includes a dual input stage 200′ as the above-described input stage 200, and an analog-to-digital conversion block 300′ which is completely similar to that described above.

The input stage 200′ includes a first voltage buffer B1, preferably a first source follower device, including a first N-channel MOS-type transistor T1' having: the respective gate terminal G1′ arranged to receive the input signal vᵢₙ; the respective drain terminal D1′ connected to the first reference voltage V_{cc}; the source terminal S1′ connected to a second reference voltage Vss, in the example, the ground voltage (0V), through a first current generator I1′; and a body connected to the source terminal S1′.

The input stage 200′ further includes a second voltage buffer B2, preferably a second source follower device, including a second N-channel MOS-type transistor T2′ having: the respective gate G2′ and drain D2′ terminals connected to the first supply voltage V_{cc}; the source terminal S2′ connected to the second reference voltage Vss (0V) through a second current generator 12′; and a body connected to the source terminal S2′.

The input stage 200′ further includes a third voltage buffer B3, preferably a third source follower device, including a third N-channel MOS-type transistor T3′ having: the respective gate terminal G3′ connected to the third reference voltage V_{ref}; the respective drain terminal D3′ connected to the first reference voltage V_{cc}; and the source terminal S3 connected to the second reference voltage Vss (0V) through a third current generator 13.

The first voltage buffer B1′ is structured or so arranged as to provide the conversion block 300′ with an output analog signal v_{in″} which is representative of the translation of the input signal vᵢₙ by an amount equal to a translation voltage V_{sh′}.

The second voltage buffer B2′ is structured or arranged as to provide the conversion block 300′ with a first reference signal V_{rif′} which is representative of the translation of the first reference voltage V_{cc} by an amount equal to the translation voltage V_{sh′}.

The third voltage buffer B3′ is structured or arranged to provide the conversion block 300′ with a second reference signal V_{rif2′} that is representative of the translation of the third reference voltage V_{ref} by an amount equal to the translation voltage V_{sh′}.

It is pointed out that the first T1′, the second T2′, and the third T3′ transistors have the same channel width/length W2/L2, and therefore the translation voltage V_{sh′} is the same for each of the transistors.

Furthermore, the first I1′, the second I2′, and the third I3′ current generators are preferably completely identical one to the other.

The conversion block 300′, in the first storing operation of the input signal vᵢₙ, is structured to store the input signal vᵢₙ as the difference between the input signal vᵢₙ and the first reference voltage V_{cc} regardless of the translation voltage V_{sh′}. This avoids the criticality of the identification of input signal voltage levels nearest to the second reference voltage V_{cc}.

Furthermore, the conversion block 300′, in the second comparison operation between the stored input signal vᵢₙ and the third reference voltage V_{ref}, is so arranged as to obtain the third reference voltage V_{ref} as the difference between the second reference voltage V_{cc} and the third reference voltage V_{ref} regardless of the translation voltage V_{sh′}. This eliminates or reduces the possibility of having an erroneous recovery of the third reference voltage V_{ref} and a consequent malfunctioning of the conversion block 300′.

Furthermore, also for this further embodiment, the presence of source follower devices allows the input stage 200′ to meet the requirements of an analog-to-digital conversion device of single-ended signals as already indicated before, and that can be found, as already specified above, in a source follower device.

As it shall be noticed, the object of the disclosure is fully achieved, since the analog-to-digital conversion device according to the described embodiments allows reducing the criticalities in the identification of the input signal to be converted at the reference level equal to 0V or another reference level.

Furthermore, the input stage with voltage buffer adapted to translate the respective input signal by a same quantity (translation voltage vₛₕ) allows the conversion device to store the input signal (vᵢₙ) and to obtain the sampling comparison signal (third reference voltage V_{ref}) regardless of the translation voltage that results to be being a function of the threshold and overdrive voltage of the transistors employed, and therefore varying with the process and the temperature.

Finally, the reliability of the proposed conversion device is also improved by the requirements of high input impedance, low input capacitance, transfer linearity, and high band, which are ensured by the type of voltage buffers (source follower devices) that is employed in the input stage.

To the above-described embodiments of the device, those of ordinary skill in the art, in order to meet contingent needs, will be able to make modifications, adaptations, and replacements of elements with functionally equivalent other ones, without departing from the scope of the following claims. Each of the characteristics described as belonging to a possible embodiment can be implemented regardless of the other embodiments described.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An analog-to-digital conversion device, comprising:
an input stage arranged to receive an input signal and to provide an output analog signal as a function of the input signal; and
an analog-to-digital conversion block arranged to receive the analog output signal and to provide a respective output digital signal, wherein the input stage comprises:
a first voltage buffer arranged to provide the analog output signal to the conversion block as a translation of the input signal of an amount equivalent to a translation voltage; and
a second voltage buffer arranged to provide a first reference signal to the conversion block that is representative of the translation of a first reference voltage of an amount equivalent to the translation voltage, so that the conversion block stores the input signal as a difference between the input signal and the first reference voltage, regardless of the translation voltage.

2. The device according to claim 1 wherein the input stage further comprises a third voltage buffer arranged to receive an incoming third reference voltage and to provide a second reference signal to the conversion block, the second reference signal representative of the translation of the third reference voltage of an amount equivalent to the translation voltage, so that the conversion block compares the stored input signal with the third reference voltage, the third reference voltage obtained as a difference between the third reference voltage and the first reference voltage, regardless of the translation voltage.

3. The device according to claim 2 wherein the first voltage buffer comprises a source follower device.

4. The device according to claim 3 wherein the second voltage buffer comprises a source follower device.

5. The device according to claim 4 wherein the third voltage buffer comprises a source follower device.

6. The device according to claim 5 wherein the first, second, and third source follower devices of the input stage comprise a first, second, and third P-channel MOS-type transistors, respectively, having a same predetermined channel width/length.

7. The device according to claim 6 wherein the first reference voltage is the ground voltage.

8. The device according to claim 6 wherein the respective drain terminals of the first, second, and third transistors are electrically connected to a common pad of the first reference voltage via a first electrical connection path.

9. The device according to claim 8 wherein the gate terminal of the second transistor is electrically coupled to the common pad via a second electrical connection path that is distinct from the first electrical connection path.

10. The device according to claim 6 wherein the translation voltage introduced by the first, second, third voltage buffers is a function of the threshold voltage and the overdrive voltage of the first, second, and third transistors, respectively.

11. The device according to claim 5 wherein the first, second, and third source follower devices of the input stage comprise a first, second, and third N-channel MOS-type transistors, respectively, having a same predetermined channel width/length ratio.

12. The device according to claim 11 wherein the first reference voltage is the supply voltage.

13. The device according to claim 11 wherein the translation voltage introduced by the first, second, and third voltage buffers is a function of the threshold voltage and the overdrive voltage of the first, second, and third transistors, respectively.

14. A circuit, comprising:
an input stage having an input and an output, the input stage comprising a first transistor having a drain and a source adapted to receive first and second voltage references, respectively, and a gate adapted to receive input signals; a second transistor having a drain and a source adapted to receive the first and second voltage references, and a gate adapted to receive the first voltage reference; and a third transistor having a drain and a source adapted to receive the first and second voltage references, respectively, and a gate adapted to receive a third reference voltage, the first transistor adapted to output on its source a translated voltage input signal, the second transistor adapted to output on its source a first reference signal, and the third transistor adapted to output on its source a second reference signal.

15. The circuit of claim 14 wherein the source of each of the first, second, and third transistors is coupled to a body of each of the first, second, and third transistors, respectively.

16. The circuit of claim 15, further comprising first, second, and third current generators coupled between the source and the second voltage reference of the first, second, and third transistors, respectively.

17. The circuit of claim 14, further comprising a conversion block having inputs coupled to the output of the input stage and adapted to receive the translated voltage input signal from the first transistor, the first reference signal from the second transistor, and the second reference signal from the third transistor.

18. The circuit of claim 14 wherein the first reference voltage comprises a supply voltage.

19. A mobile device, comprising:
a circuit that comprises an input stage having an input and an output, the input stage comprising a first transistor having a drain and a source adapted to receive first and second voltage references, respectively, and a gate adapted to receive input signals; a second transistor having a drain and a source adapted to receive the first and second voltage references, and a gate adapted to receive the first voltage reference; and a third transistor having a drain and a source adapted to receive the first and second voltage references, respectively, and a gate adapted to receive a third reference voltage, the first transistor adapted to output on its source a translated voltage input signal, the second transistor adapted to output on its source a first reference signal, and the third transistor adapted to output on its source a second reference signal.

20. The circuit of claim 19, further comprising a conversion block having inputs coupled to the output of the input stage and adapted to receive the translated voltage input signal from the first transistor, the first reference signal from the second transistor, and the second reference signal from the third transistor.

21. The mobile device of claim 20, further comprising first, second, and third current generators coupled between the source and the second voltage reference of the first, second, and third transistors, respectively.
